(19) United States
(12) Patent Application Publication
(10) Pub. No.: US 2026/0268964 A1
(43) Pub. Date: Sep. 10, 2026

(54) MEMORY CHIP AND OFF-CHIP DRIVER

(71) Applicant: NANYA TECHNOLOGY CORPORATION, New Taipei City (TW)

(72) Inventors: Chih-Jen Chen, New Taipei City (TW); Chang-Ting Wu, New Taipei City (TW)

(73) Assignee: NANYA TECHNOLOGY CORPORATION, New Taipei City (TW)

(21) Appl. No.: 19/072,866

(22) Filed: Mar. 6, 2025

(51) Int. Cl. G11C 11/4096

(52) U.S. Cl. CPC G11C 11/4096

(57) ABSTRACT

A memory chip and an off-chip driver (OCD). The OCD includes a output driver and a bulk selector. The output driver comprises a first transistor and configured to output a memory data to a signal pad. The bulk selector is coupled to a bulk terminal of the first transistor. The bulk selector is configured to: provide a first bulk voltage to the bulk terminal of the first transistor according to an enable signal; and provide a second bulk voltage to the bulk terminal of the first transistor according to the enable signal. The first transistor has a first threshold voltage when the first bulk voltage is provided, and the first transistor has a second threshold voltage when the second bulk voltage is provided. An absolute value of the second threshold voltage is greater than an absolute value of the first threshold voltage.

### BACKGROUND

### 1. Technical Field

The disclosure generally relates to a chip and a driver, and more particularly to a memory chip and an off-chip driver.

### 2. Description of Related Art

With the developments of memory, more and more memories are designed in transistors with low threshold voltages for higher operating speed. However, the lower threshold voltage also leads to a higher leakage current, thereby worsening signal integrity of the memory.

### SUMMARY

Accordingly, the disclosure is directed to a memory chip and an off-chip driver which may be capable of reducing leakage current and improving signal integrity.

The memory chip of the present disclosure includes a signal pad, a signal output circuit, and an off-chip driver (OCD). The signal output circuit is coupled to the signal pad. The signal output circuit is enabled by an enable signal to output a data signal to the signal pad. The OCD includes a output driver and a bulk selector. The output driver comprises a first transistor coupled to the signal pad. The output driver is configured to output a memory data to the signal pad. The bulk selector is coupled to a bulk terminal of the first transistor. The bulk selector is configured to: provide a first bulk voltage to the bulk terminal of the first transistor when the signal output circuit is disabled by the enable signal; and provide a second bulk voltage to the bulk terminal of the first transistor when the signal output circuit is enabled by the enable signal. The first transistor has a first threshold voltage when the first bulk voltage is provided, and the first transistor has a second threshold voltage when the second bulk voltage is provided. An absolute value of the second threshold voltage is greater than an absolute value of the first threshold voltage.

The off-chip driver (OCD) of the present disclosure includes a output driver and a bulk selector. The output driver comprises a first transistor coupled to the signal pad. The output driver is configured to output a memory data to the signal pad. The bulk selector is coupled to a bulk terminal of the first transistor. The bulk selector is configured to: provide a first bulk voltage to the bulk terminal of the first transistor according to an enable signal; and provide a second bulk voltage to the bulk terminal of the first transistor according to the enable signal. The first transistor has a first threshold voltage when the first bulk voltage is provided, and the first transistor has a second threshold voltage when the second bulk voltage is provided. An absolute value of the second threshold voltage is greater than an absolute value of the first threshold voltage.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a memory chip in accordance with some embodiments.

FIG. 2A illustrates a schematic diagram of a bulk selector in accordance with some embodiments.

FIG. 2B illustrates a schematic diagram of a bulk selector in accordance with some embodiments.

FIG. 3 illustrates a memory chip in accordance with some embodiments.

FIG. 4 illustrates a memory chip in accordance with some embodiments.

### DESCRIPTION OF THE EMBODIMENTS

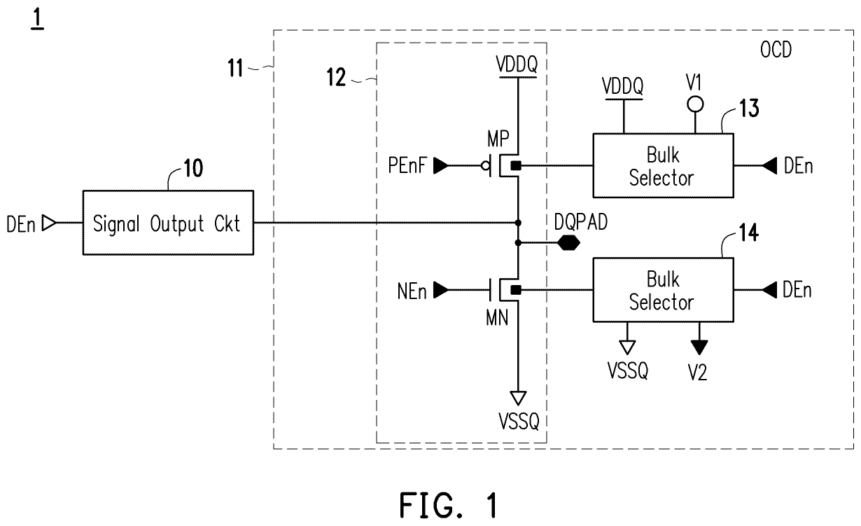

FIG. 1 illustrates a memory chip 1 in accordance with some embodiments. The memory chip 1 includes a signal output circuit 10, an off-chip driver (OCD) 11, and a signal pad DQPAD.
For example, the memory chip may be a Double Data Rate (DDR) RAM memory chip that implement DDR interfacing scheme for high-speed data transfer. The signal pad DQPAD may be a pad queue pad used for data transmission.

Generally speaking, the signal pad DQPAD is shared by the signal output circuit 10 and the OCD 11 for outputting signals. Specifically, in a memory accessing mode, the OCD 11 may be configured to output data read from a memory (not shown in FIG. 1) to the signal pad DQPAD for external access. On the other hand, in some operation scenarios when the OCD 11 is not functioning, the signal pad DQPAD may be provided for transmitting test signals. In a test mode when the OCD 11 is disabled, the signal output circuit 10 may be enabled for transmitting the test signals to the signal pad DQPAD.

However, in the test mode, a voltage on the signal pad PQPAD may still be affected by the OCD 11 due to leakage even when a disable voltage level is provided to the OCD 11. To reduce leakage current and improve signal integrity, the memory chip 1 with the OCD 11 is provided. The OCD 11 includes an output driver 12 and bulk selectors 13, 14. The output driver 12 may be configured to receive output control signals PEnF, NEn to output a memory data to the signal pad DQPAD. The output driver 12 includes transistors MP, MN. The transistors MP, MN are respectively a P-type metal-oxide-silicon (PMOS) transistor and an N-type metal-oxide-silicon (NMOS) transistor. The transistors MP, MN are coupled in series between the reference voltages VDDQ, VSSQ, with the source terminals of the transistors MP, MN respectively coupled to receive the reference voltages VDDQ, VSSQ, and the signal pad DQPAD is coupled at a node between drain terminals of the transistors MP, MN. The bulk terminals of the transistors MP, MN are respectively controlled by the bulk selectors 13, 14.

Specifically, each of the bulk selectors 13,14 may receive different bulk voltages, and configured to provide one of the received bulk voltages to the bulk terminal of the coupled transistor. By providing different bulk voltages to the transistor, a threshold voltage of such transistor may be correspondingly adjusted. In this way, the threshold voltage of the transistor in the output driver 12 may be elevated to reduce leakage current

More particularly, for the PMOS transistor MP, the bulk selector 13 controlling the bulk terminal of the transistor MP is configured to provide one of the reference voltage VDDQ and a control voltage V1 to the bulk terminal of the transistor MP according to an enable signal DEn. Further, the bulk selector 13 receives an enable signal DEn which is coupled to an enable terminal of the signal output circuit 10, so that the bulk selector 13 may properly obtain information on whether the signal output circuit 10 is enabled or not. The bulk selector 13 determines which one of the reference voltage VDDQ and the control voltage V1 is provided to the bulk terminal of the transistor MP according to the enable signal DEn. When the signal output circuit 10 is disabled by the enable signal DEn, the bulk selector 13 may provide the reference voltage VDDQ as a first bulk voltage to the bulk terminal of the transistor MP. When the signal output circuit 10 is enabled by the enable signal DEn, the bulk selector 13 may provide the control voltage V1 as a second bulk voltage to the bulk terminal of the transistor MP.

Generally speaking, the threshold voltage of the PMOS transistor is a negative voltage. The PMOS transistor is turned on and becomes conductive to allow a saturation current flowing through the PMOS transistor when an applied voltage difference between the gate and source terminals (also denoted Vgs) is less than the threshold voltage. On the other hand, the PMOS transistor is cutoff and becomes nonconductive to forbid the saturation current flowing through it when the Vgs is greater than the threshold voltage. However, leakage current still occurs even when the PMOS transistor is cutoff.

In this embodiment, when the reference voltage VDDQ taken as the first bulk voltage is provided to the bulk and source terminals of the transistor MP, the threshold voltage of the transistor MP may be set as a first threshold voltage. On the other hand, when the control voltage V1 higher than the reference voltage VDDQ is taken as the second bulk voltage and is provided to the bulk terminal of the transistor MP, the threshold voltage of the transistor MP may be set as a second threshold voltage. The second threshold voltage is less than the first threshold voltage, but an absolute value of the second threshold voltage is higher than an absolute value of the first threshold voltage since the first and second threshold voltages are negative voltages. In this way, the lower threshold voltage can keep the leakage current lower when the transistor MP is cutoff even when the Vgs applied to the transistor MP is unchanged. The lower threshold voltage of the transistor MP may prevent the voltage on the signal pad DQPAD from being affecting by the leakage current, thereby maintaining the signals transmitted by the signal output circuit 10 to the signal pad DQPAD correct.

On the other hand, for the NMOS transistor MN, the bulk selector 14 controlling the bulk terminal of the transistor MN is configured to provide one of the reference voltage VSSQ and a control voltage V2 to the bulk terminal of the transistor MN according to an enable signal DEn. Further, the bulk selector 14 also receives the signal DEn which is coupled to the enable terminal of the signal output circuit 10, so that the bulk selector 14 may properly obtain information on whether the signal output circuit 10 is enabled or not. The bulk selector 14 determines which one of the reference voltage VSSQ and the control voltage V2 is provided to the bulk terminal of the transistor MN according to the enable signal DEn. When the signal output circuit 10 is disabled by the enable signal DEn, the bulk selector 14 may provide the reference voltage VSSQ as a third bulk voltage to the bulk terminal of the transistor MN. When the signal output circuit 10 is enabled by the enable signal DEn, the bulk selector 14 may provide the control voltage V2 as a fourth bulk voltage to the bulk terminal of the transistor MN.

Generally speaking, the threshold voltage of the NMOS transistor is a positive voltage. The NMOS transistor is turned on and becomes conductive to allow a saturation current flowing through the NMOS transistor when an applied voltage difference between the gate and source terminals (also denoted Vgs) is greater than the threshold voltage. On the other hand, the NMOS transistor is cutoff and becomes nonconductive to forbid the saturation current flowing through it when the Vgs is less than the threshold voltage. However, leakage current still occurs even when the NMOS transistor is cutoff.

In this embodiment, when the reference voltage VSSQ taken as the third bulk voltage is provided to the bulk and source terminals of the transistor MN, the threshold voltage of the transistor MN may be set as a third threshold voltage. On the other hand, when the control voltage V2 lower than the reference voltage VSSQ is taken as the fourth bulk voltage and is provided to the bulk terminal of the transistor MN, the threshold voltage of the transistor MN may be set as a fourth threshold voltage. The fourth threshold voltage is greater than the third threshold voltage, and an absolute value of the fourth threshold voltage is also higher than an absolute value of the third threshold voltage. In this way, the higher threshold voltage can keep the leakage current lower when the transistor MN is cutoff even when the Vgs applied to the transistor MN is unchanged. The higher threshold voltage of the transistor MN may prevent the voltage on the signal pad DQPAD from being affecting by the leakage current, thereby maintaining the signals transmitted by the signal output circuit 10 to the signal pad DQPAD correct.

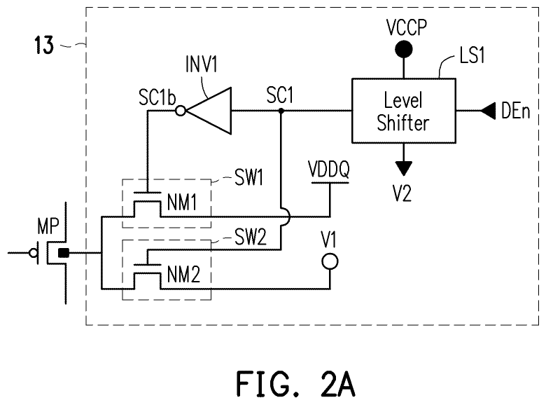

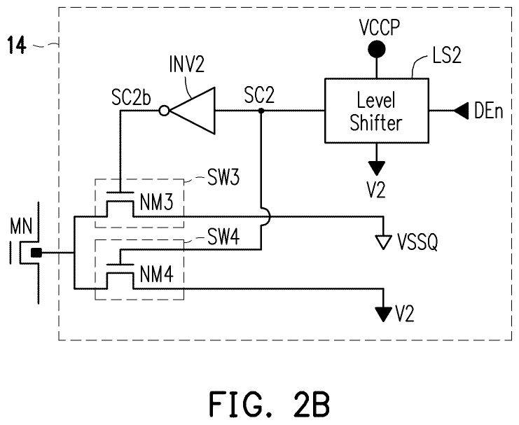

FIG. 2A illustrates a schematic diagram of a bulk selector 13 in accordance with some embodiments. The bulk selector 13 includes a first switch SW1, a second switch SW2, an inverter INV1, and a level shifter LS1. The first switch SW1 is coupled between the reference voltage VDDQ and the bulk terminal of the transistor MP for selectively providing the reference voltage VDDQ to the bulk terminal of the transistor MP. Further, the second switch SW2 is coupled between the control voltage V1 and the bulk terminal of the transistor MP for selectively providing the control voltage V1 to the bulk terminal of the transistor MP.

In this embodiment, the first switch SW1 is implemented by a transistor NM1, with its drain and source terminals respectively coupled to the reference voltage VDDQ and the bulk terminal of the transistor MP. The second switch SW2 is implemented by a transistor NM2, with its drain and source terminals respectively coupled to the control voltage V1 and the bulk terminal of the transistor MP. The enable signal DEn is used to control which one of the first switch SW1 and the second switch SW2 is responsible to supply the bulk terminal of the transistor MP. However, since the control voltage V1 has a voltage higher than that of the reference voltage VDDQ has, a level shifter LS1 is used to raise an enable voltage level of the enable signal DEn to properly turn on the first and second switches SW1, SW2.

Specifically, the level shifter LS1 is configured generate a switch control signal SC1 by raising the enable voltage level of the enable signal DEn to a voltage level of a reference voltage VCCP, and lowering a disable voltage level of the enable signal DEn to a voltage level of the control signal V2. The switch control signal SC1 is provided to control the second switch SW2, and more particularly to control a gate terminal of the transistor NM2 of the second switch SW2. Further, the switch control signal SC1 is inputted to an inverter INV1 to generate an inverted switch control signal SC1b. The inverted switch control signal SC1b is provided to control the first switch SW1, and more particularly to control a gate terminal of the transistor NM1 of the first switch SW1. Since the voltage level of the reference voltage VCCP is higher than the voltage level of the control signal V1, so that the first and second switches SW1, SW2 may be properly turned on to pass the reference voltage VDDQ and/or the control voltage V1 to the bulk terminal of the transistor MP.

FIG. 2B illustrates a schematic diagram of a bulk selector 14 in accordance with some embodiments. The bulk selector 14 includes a third switch SW3, a fourth switch SW4, an inverter INV2, and a level shifter LS2. The third switch SW3 is coupled between the reference voltage VSSQ and the bulk terminal of the transistor MN for selectively providing the reference voltage VSSQ to the bulk terminal of the transistor MN. Further, the fourth switch SW4 is coupled between the control voltage V2 and the bulk terminal of the transistor MN for selectively providing the control voltage V2 to the bulk terminal of the transistor MN.

In this embodiment, the third switch SW3 is implemented by a transistor NM3, with its drain and source terminals respectively coupled to the reference voltage VSSQ and the bulk terminal of the transistor MN. The fourth switch SW4 is implemented by a transistor NM4, with its drain and source terminals respectively coupled to the control voltage V2 and the bulk terminal of the transistor MN. The enable signal DEn is used to control which one of the third switch SW3 and the fourth switch SW4 is responsible to supply the bulk terminal of the transistor MN. However, since the control voltage V2 has a voltage lower than that of the reference voltage VSSQ has, a level shifter LS2 is used to lower a disable voltage level of the enable signal DEn to properly turn off the third and fourth switches SW3, SW4.

Specifically, the level shifter LS2 is configured generate a switch control signal SC2 by raising the enable voltage level of the enable signal DEn to a voltage level of a reference voltage VCCP, and lowering a disable voltage level of the enable signal DEn to a voltage level of the control signal V2. The switch control signal SC2 is provided to control the fourth switch SW4, and more particularly to control a gate terminal of the transistor NM4 of the fourth switch SW4. Further, the switch control signal SC2 is inputted to an inverter INV2 to generate an inverted switch control signal SC2b. The inverted switch control signal SC2b is provided to control the third switch SW3, and more particularly to control a gate terminal of the transistor NM3 of the third switch SW3. Since the disable voltage levels of the switch control signal SC2 and the inverted switch control signal SC2b are low enough to turn off the third and fourth switches SW3, SW4 without leakage, the reference voltage VSSQ and/or the control voltage V2 may be properly passed to the bulk terminal of the transistor MN.

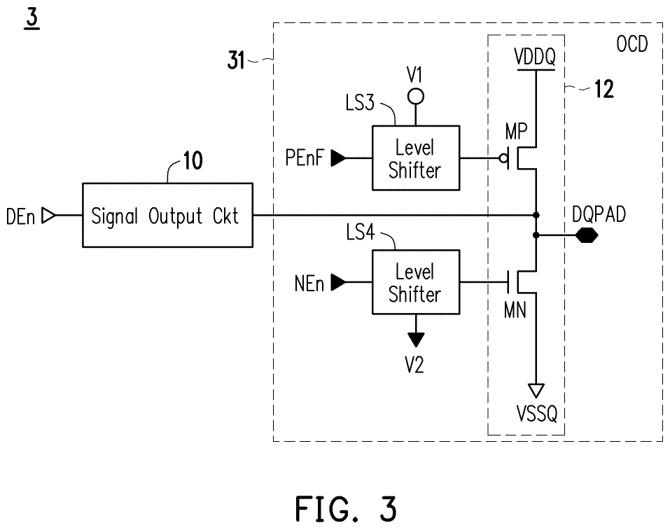

FIG. 3 illustrates a memory chip 3 in accordance with some embodiments. The memory chip 3 in FIG. 3 is similar to the memory chip 1 in FIG. 1, and thus the same components are denoted by the same symbols. Please refer to paragraph above in relation with FIG. 1 for descriptions of those components, which are not repeated herein.

The different between the memory chip 3 and the memory chip 1 is that the OCD 11 in the memory chip 1 is replaced by the OCD 31 in the memory chip 3, in which level shifters LS3, LS4 are added and the bulk selectors 13, 14 are removed. Specifically, the level shifter LS3 is coupled to the transistor MP. The level shifter LS3 may be configured to raise a voltage level of the output control signal PEnF to a voltage level of the control signal V1. In this embodiment, instead of increasing the absolute value of the threshold voltage, an alternative approach of pulling up the gate voltage to be higher than the source voltage of the transistor MP is adopted. More particularly, the transistor MP is controlled by a voltage difference of the Vgs subtracting the threshold voltage, and is turned on or conductive when the Vgs is lower than the threshold voltage. By raising the voltage level received at the gate terminal of the transistor MP to the voltage level of the control voltage V1, the gate voltage is pulled to be higher than the voltage level of the reference voltage VDDQ that the transistor MP received at the source terminal, so the transistor MP may be controlled at a deeper cutoff mode, thereby reducing leakage current flowing to the signal pad DQPAD.

Similarly, the level shifter LS4 is coupled to the transistor MN. The level shifter LS4 may be configured to lower a voltage level of the output control signal NEn to a voltage level of the control signal V2. In this embodiment, instead of increasing the absolute value of the threshold voltage, an alternative approach of pulling down the gate voltage to be lower than the source voltage of the transistor MN is adopted. More particularly, the transistor MN is controlled by a voltage difference of the Vgs subtracting the threshold voltage, and is turned on or conductive when the Vgs is higher than the threshold voltage. By pulling down the voltage level received at the gate terminal of the transistor MN to the voltage level of the control voltage V2, the gate voltage is pulled to be lower than the voltage level of the reference voltage VSSQ that the transistor MN received at the source terminal, so the transistor MN may be controlled at a deeper cutoff mode, thereby reducing leakage current flowing to the signal pad DQPAD.

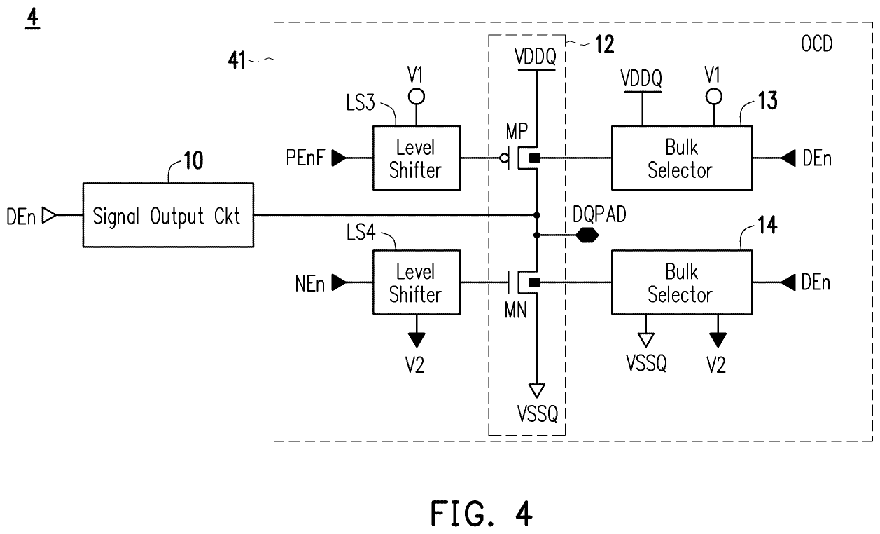

FIG. 4 illustrates a memory chip 4 in accordance with some embodiments. The memory chip 4 in FIG. 4 is similar to the memory chip 1 in FIG. 1, and thus the same components are denoted by the same symbols. In this embodiment, the bulk selectors 13, 14 and the level shifters LS3, LS4 are added in the OCD 41 of the memory chip 4. Please refer to paragraphs above in relation to FIGS. 1 and 2 for descriptions about the bulk selectors 13, 14, and refer to paragraphs above in relation to FIG. 3 for descriptions about the level shifters LS3, LS4, which are not repeated herein

In summary, the memory chip and the OCD may properly reduce leakage current flowing to the signal pad, improving signal integrity of the memory chip.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory chip, comprising:
a signal pad;
a signal output circuit coupled to the signal pad, the signal output circuit being enabled by an enable signal to output a data signal to the signal pad; and
an off-chip driver (OCD) comprising:
an output driver comprising a first transistor coupled to the signal pad, the output driver being configured to output a memory data to the signal pad; and
a bulk selector coupled to a bulk terminal of the first transistor, the bulk selector being configured to:
provide a first bulk voltage to the bulk terminal of the first transistor when the signal output circuit is disabled by the enable signal; and
provide a second bulk voltage to the bulk terminal of the first transistor when the signal output circuit is enabled by the enable signal.

2. The memory chip of claim 1, wherein the first transistor has a first threshold voltage when the first bulk voltage is provided, and the first transistor has a second threshold voltage when the second bulk voltage is provided, wherein an absolute value of the second threshold voltage is greater than an absolute value of the first threshold voltage.

3. The memory chip of claim 1, wherein the first transistor is a P-type metal-oxide-silicon (PMOS) transistor, and the second bulk voltage is higher than the first bulk voltage.

4. The memory chip of claim 1, wherein the first transistor is an N-type metal-oxide-silicon (NMOS) transistor, and the first bulk voltage is higher than the second bulk voltage.

5. The memory chip of claim 1, wherein the bulk selector is configured to selectively provide one of the first bulk voltage and the second voltage to the bulk terminal of the first transistor according to the enable signal.

6. The memory chip of claim 1, wherein the bulk selector is a first bulk selector and the output driver comprises:
a second transistor coupled in series with the first transistor between a first reference voltage and a second reference voltage, and the signal pad is coupled between the first transistor and the second transistor,
wherein the COD comprises:
a second bulk selector coupled to a bulk terminal of the second transistor, the second bulk selector being configured to:
provide a third bulk voltage to the bulk terminal of the second transistor when the signal output circuit is disabled by the enable signal; and
provide a fourth bulk voltage lower than the third bulk voltage to the bulk terminal of the second transistor when the signal output circuit is enabled by the enable signal.

7. The memory chip of claim 1, wherein the bulk selector comprises:
a first switch controlled by the enable signal to selectively provide the first bulk voltage to the bulk terminal of the first transistor; and
a second switch controlled by an inverted enable signal to selectively provide the second bulk voltage to the bulk terminal of the first transistor.

8. The memory chip of claim 7, wherein the bulk selector comprises:
a first level shifter configured to generate a switch control signal to control the second switch by raising a first enable voltage level of the enable signal to a second enable voltage level and lowering a first disable voltage level of the enable signal to a second disable voltage level; and
an inverter coupled to the first level shifter, the inverter being configured generate an inverted switch control signal to control the first switch by inverting the switch control signal.

9. The memory chip of claim 1, wherein the first transistor is a PMOS transistor controlled by a first output control signal, the OCD comprises:
a second level shifter coupled to the first transistor, the second level shifter being configured to raise a first voltage level of the first output control signal, which is used to disable the first transistor, to a second voltage level.

10. The memory chip of claim 9, wherein the output driver comprises:
a second transistor of an NMOS transistor coupled in series with the first transistor between a first reference voltage and a second reference voltage, the second transistor is controlled by a second output control signal,
wherein the OCD comprises:
a third level shifter coupled to the second transistor, the third level shifter being configured to lower a third voltage level of the second output control signal, which is used to disable the second transistor, to a fourth voltage level.

11. The memory chip of claim 10, wherein the second voltage level is higher than a voltage level of the first reference voltage, and the fourth voltage level is lower than a voltage level of the second reference voltage.

12. An off-chip driver (OCD), adapted to be coupled to a signal pad, the OCD comprising:
an output driver comprising a first transistor coupled to the signal pad, the output driver being configured to output a memory data to the signal pad; and
a bulk selector coupled to a bulk terminal of the first transistor, the bulk selector being configured to:
provide a first bulk voltage to the bulk terminal of the first transistor according to an enable signal; and
provide a second bulk voltage to the bulk terminal of the first transistor according to the enable signal.

13. The OCD of claim 12, wherein the first transistor has a first threshold voltage when the first bulk voltage is provided, and the first transistor has a second threshold voltage when the second bulk voltage is provided, wherein an absolute value of the second threshold voltage is greater than an absolute value of the first threshold voltage.

14. The OCD of claim 12, wherein the first transistor is a P-type metal-oxide-silicon (PMOS) transistor, and the second bulk voltage is higher than the first bulk voltage.

15. The OCD of claim 12, wherein the first transistor is an N-type metal-oxide-silicon (NMOS) transistor, and the first bulk voltage is higher than the second bulk voltage.

16. The OCD of claim 12, wherein the bulk selector is configured to selectively provide one of the first bulk voltage and the second voltage to the bulk terminal of the first transistor according to the enable signal.

17. The OCD of claim 12, wherein the bulk selector is a first bulk selector and the output driver comprises:
a second transistor coupled in series with the first transistor between a first reference voltage and a second reference voltage, and the signal pad is coupled between the first transistor and the second transistor,
wherein the OCD comprises:
a second bulk selector coupled to a bulk terminal of the second transistor, the second bulk selector being configured to:
provide a third bulk voltage to the bulk terminal of the second transistor when the enable signal is enabled; and
provide a fourth bulk voltage lower than the third bulk voltage to the bulk terminal of the second transistor when the enable signal is enabled.

18. The OCD of claim 12, wherein the bulk selector comprises:
a first switch controlled by the enable signal to selectively provide the first bulk voltage to the bulk terminal of the first transistor; and
a second switch controlled by an inverted enable signal to selectively provide the second bulk voltage to the bulk terminal of the first transistor.

19. The OCD of claim 18, wherein the bulk selector comprises:
a first level shifter configured to generate a switch control signal to control the second switch by raising a first enable voltage level of the enable signal to a second enable voltage level and lowering a first disable voltage level of the enable signal to a second disable voltage level; and
an inverter coupled to the first level shifter, the inverter being configured generate an inverted switch control signal to control the first switch by inverting the switch control signal.

20. The OCD of claim 12, wherein the first transistor is a PMOS transistor controlled by a first output control signal, the OCD comprises:
a second level shifter coupled to the first transistor, the second level shifter being configured to raise a first voltage level of the first output control signal, which is used to disable the first transistor, to a second voltage level.

21. The OCD of claim 20, wherein the output driver comprises:
a second transistor of an NMOS transistor coupled in series with the first transistor between a first reference voltage and a second reference voltage, the second transistor is controlled by a second output control signal,
wherein the OCD comprises:
a third level shifter coupled to the second transistor, the third level shifter being configured to lower a third voltage level of the second output control signal, which is used to disable the second transistor, to a fourth voltage level.

22. The OCD of claim 21, wherein the second voltage level is higher than a voltage level of the first reference voltage, and the fourth voltage level is lower than a voltage level of the second reference voltage.
